(19) United States
(12) Patent Application Publication
(10) Pub. No.: US 2026/0212918 A1
(43) Pub. Date: Jul. 23, 2026

(54) CIRCUITS AND METHOD FOR FAST, ENERGY EFFICIENT 6T SRAM ARRAYS USING HARVESTED DATA

(71) Applicant: Metis Microsystems, LLC, Newtown, CT (US)

(72) Inventor: Azeez BHAVNAGARWALA, Newtown, CT (US)

(73) Assignee: Metis Microsystems, LLC, Newtown, CT (US)

(21) Appl. No.: 19/001,095

(22) Filed: Dec. 24, 2024

Related U.S. Application Data
(63) Continuation of application No. 17/953,091, filed on Sep. 26, 2022, now abandoned.
Application No. 17/953,091 is a continuation of application No. 17/827,763, filed on May 29, 2022, now Pat. No. 12,224,000.
(60) Provisional application No. 63/194,053, filed on May 27, 2021.
(60) Provisional application No. 63/248,491, filed on Sep. 26, 2021.

(51) Int. Cl. G11C 11/4096; G11C 11/4074; G11C 11/4094

(52) U.S. Cl. CPC G11C 11/4096; G11C 11/4074; G11C 11/4094

(57) ABSTRACT

A transistor memory device includes transistor storage elements storing a capacitance at each transistor storage element. Each transistor storage element includes a word line port that selects a bitcell and a bitline. Each transistor storage element performs a read data access from or a write data access to each remaining transistor storage element to increase a SNM. The device includes a harvest node configured to store a harvested charge transferred from the bitline. The transistor memory device includes a capacitor divider between the bitline and the harvest node of a first transistor storage element and configured to maintain a voltage swing on the bitline. The device further includes a harvest circuit configured to, in response to the read data access performed by the first transistor storage element, decouple the harvest node from a ground and invert a voltage equal to a potential difference between the bitline and the harvest node.

### CROSS REFERENCE TO RELATED APPLICATIONS

This application is a continuation of U.S. patent application Ser. No. 17/953,091, filed Sep. 26, 2022, which claims priority to and is a continuation of U.S. patent application Ser. No. 17/827,763, filed May 29, 2022 entitled “Fast, Energy Efficient 6T SRAM Arrays Using Harvested Data”, which claims priority to U.S. Provisional Application No. 63/194,053, filed May 27, 2021, entitled “Fast, Energy Efficient 6T SRAM Arrays using Harvested Data”, and U.S. Provisional Application No. 63/248,491, filed Sep. 26, 2021, entitled “Fast, Energy Efficient 6T SRAM Arrays using Harvested Data”, each of which is hereby incorporated by reference in its entirety.

### FIELD

The present disclosure generally relates to digital integrated circuits. In particular, the present disclosure is related circuits and methods for fast, energy efficient 6T SRAM arrays using harvested data.

### BACKGROUND

CMOS 6T SRAM bitcells have served as the primary workhorse technology for embedded memories across a broad range of applications-HPC. in datacenter server CPUs & GPUs, Domain Specific Accelerators for AI workloads, power constrained application processors in mobile devices and in ultra-low cost and pervasive edge/end-point IoT devices or wireless. devices supporting AI workloads. Primary reasons. for this dominant presence across as wide a range of applications are (1) Fast access and cycle time (2) compatibility across CMOS logic platform technologies-not requiring additional process steps or masks as eDRAM, MRAM, embedded Flash technologies do and (3) lowest. operating voltages across all memory technology candidates making it the most energy efficient choice.

While it's compatibility with CMOS logic platform technologies have enabled SRAM bitcells to scale (FIGS. 1a and 1c) their footprint 50% every technology node, scaling of SRAM operating voltages (FIG. 1b) and improvements in SRAM energy efficiency has been much harder.

The quantization of device width. in FinFET SRAM bitcells (FIG. 2) in tandem with the uncertainty of electrical characteristics of small geometry bitcell transistors require Assist circuit schemes for dense and high current bitcells to improve yield at nominal and low voltages. The competing requirements for Read Vs Write margins, leakage Vs performance, density Vs VMIN etc., in the presence of increased bitcell variability create significant challenges in array design for practically all of the different application needs—making the above trade-offs even more challenging at low voltages. Assist techniques such as WL, under-drive to improve Read stability margins or negative BLs to improve Write margins come with a combination of penalties imposed on performance, energy efficiency and area efficiency where the energy overhead of using Assist techniques can raise the energy consumption of an SRAM access by as much as 26%-31% with an area overhead (assuming 256b/BL) of 5%-11% to support the Write assist techniques alone.

In this proposal, simple, compact and robust harvesting circuits described following a review of conventional SRAM circuits. Elimination of the effects of MOS device electrical uncertainties on Read/Write Energy efficiency and performance are shown to further improve performance and the energy efficiency.

Differential sense amplifiers (DSA): Latch-type sense amplifiers shown in FIG. 3—typically used in SRAM arrays, achieve fast action due to strong positive feedback and can resolve small BL voltage signals with ΔVmin of merely 50-100 mV making them energy efficient as well. However, the WL pulse width—the time required, to build signal across a BL pair, must be sufficiently wide for the slowest bitcell in the array at any given operating voltage (FIG. 4). Sense-amp offsets, leakage noise from unselected bitcells, signal loss across column mux transistors and read current uncertainty-all widen the minimum WL pulse width required, which increases the Pt swing for all bitcells. Wider pulse widths in tandem with increased read current variability (from larger arrays) give all bitcells faster than the slowest one much more time to discharge the BL increasing their signal swing closer to VDD. The WL pulse width equals the minimum cycle time when large arrays support a pipelined access at the same clock rate as the processor core. The performance degradation in large arrays gets worse because the left end of the read current distribution corresponds to an even smaller current requiring even wider WL pulse widths-setting limits on maximum SRAM pipeline clock frequency.

Read Assist: Read and Write Assist circuits have become essential to enabling SRAM voltage scaling given the statistical variations in single fin bitcell devices and the substantial degradation of its noise margins. While improvements in minimum operating voltage have been reported with commonly used Read and Write Assist circuit schemes that favorably bias the bitcell terminals to improve noise margins for Read or Write, these techniques add energy and area overheads that diminish the benefits of operating at lower voltages.

For example, the commonly used Read assist of WL underdrive (WLUD) limits the maximum WL voltage to below VDD to improve cell stability from a higher cell beta ratio (PD/PG strength). The gate overdrive of an average cell pass transistor sees a marginal reduction in read current, but the reduction of read current from under-driving the WL in the slowest bitcell (that sets the minimum on WL pulse width) is much larger since the gate overdrive in that cell=VDD−VTmax is small to begin with, given VTmax from VT fluctuations in large arrays (162 nMb in). Moreover, the Write margin is reduced since WL is also underdriven during a Write.

Write Assist: Bitcells with large random VT fluctuations can fail a Write attempt if the PU PFET holding a ‘1’ at the storage node is stronger than the PG NFET through which a ‘0’ on the BL is attempting a Write. Write margins can be improved by weakening the PU PFET and/or strengthening the PG NFET. Lowering or collapsing the supply terminal of columns selected for a Write thus improves the Write Margin of the selected cell by weakening the PU PFET but comes at a substantial energy overhead since the total capacitance the cell supply terminal sees includes not just the diffusion capacitance of the pull-up PMOS bitcell transistors connected to the cell supply terminal but also the total diffusion capacitance of the storage node the supply terminal is connected to through an ‘on’ PMOS (FIG. 5a) and the gate input capacitance (of PU1 and PD1 in FIG. 5a) that storage node ‘Bitx’ drives. In total, this capacitance is about 4× the device capacitance seen by the BL terminal of the cell making the energy overhead to recover the voltage at the supply terminal substantial (FIGS. 5b and 5c).

Asserting a Negative BL also improve write margins and write VMIN from strengthening the PG NFET by increasing its VGS with a negative voltage asserted on the BL attempting to write a ‘0’. The Energy overheads are over 30% in addition to area overheads of 5%-10%.

3.1 Array architecture: To be able to make quantitative comparisons between proposed circuits and those used by baseline industry standard designs, a simple, widely used 128Kb SRAM Array architecture (FIG. 6a) in 16 nm FF CMOS from TSMC is assumed. 16 nm high performance and low power device parameter decks from ASU are used in HSPICE circuit simulations with technology parameters for 16 nm CMOS wiring parasitics from IEDM (FIG. 6b) publications by the Foundry. Cell Dimensions (FIG. 2) and wiring parasitics of this SRAM array (Caption of FIG. 6a) are used in the design of peripheral circuits to compare metrics of performance and energy efficiency using either proposed or conventional circuits. Lateral and vertical dimensions of the array assume a 70% array efficiency where a 20% overhead in X and Y directions are assumed for peripheral circuits.

3.2 CMOS platform technology: The 2014 TSMC 16 nm FinFET was preferred since the array design is more generous in sharing measurement data than the more recent publications from industry members in general. For example, the (measurement data based) dependence of Write VMIN as a function of the cell voltage lowering-that enables me to calculate-the Write assist energy overhead from using the cell voltage lowering scheme (popular with recent TSMC and with Intel designs).

3.3 Variability impact on performance: Variability in bitcell VT has impact on VMIN and on bitpath latency and on its uncertainty. Variability in sense amp transistors impacts bitpath latency and its uncertainty. Other contributions to bitpath latency and its uncertainty come from bitline leakage noise and Read assist schemes such as WLUD that substantially degrade bitpath latency and its uncertainty. Attempts to column multiplex on the BL during a Read access degrades the bitpath latency uncertainty even further.

### SUMMARY

In one or more embodiments, a transistor memory device includes a set of transistor storage elements storing a collective capacitance including (1) a capacitance at a source terminal of each p-channel field-effect transistors (PFETs) from a set of PFETs, (2) a capacitance at each transistor storage element from the set of transistor storage elements electrically connected to a storage node and (3) a capacitance at a gate input of a set of inverter transistors from the set of transistor storage elements. Each transistor storage element from the set of transistor storage elements includes a word line port configured to select (a) a bitcell and (b) a first bitline or a second bitline. Each transistor storage element from the set of transistor storage elements is configured to perform (i) a read data access from or (ii) a write data access to each remaining transistor storage element from the set of transistor storage elements, to increase a static noise margin in response to a decrease of a read current and a voltage on the storage node. The collective capacitance of the plurality of transistor storage elements is greater than a terminal capacitance of the selected bitline. The transistor memory device further includes a harvest node electrically coupled to a ground. The harvest node is configured to store a harvested charge transferred from the selected bitline to increase an output voltage at the harvest node. The transistor memory device further includes a capacitor divider electrically connected between the selected bitline and the harvest node of a first transistor storage element from the set of transistor storage elements that shares the selected bitline and the harvest node. The capacitor divider is configured to maintain a voltage swing on the selected bitline. The transistor memory device further includes a harvest circuit electrically coupled to the harvest node and configured to, in response to the read data access performed by the first transistor storage element, decouple the harvest node from the ground and invert a voltage equal to a potential difference between the selected bitline and the harvest node.

### BRIEF DESCRIPTION OF DRAWINGS

FIGS. 1A and 1C are illustrations of graphs depicting SRAM Density Scaling Vs Node and Vs Year, according to one or more embodiments.

FIG. 1B is an illustration of a graph depicting SRAM voltage scaling, according to one or more embodiments.

FIG. 2 illustrates a schematic circuit (top) and FinFET based layout for Dense 6T SRAM cell (bottom) with 1 fin for PG, PU, PD devices, according to one or more embodiments.

FIG. 3 illustrates a schematic circuit of a conventional high input resistance latch-type Differential Sense Amp (DSA), according to one or more embodiments.

FIG. 4 is an illustration of a graph depicting presence of variability. along SRAM bitpath increases signal development time and BL voltage swing-degrading read performance and read energy efficiency with conventional DSAs, according to one or more embodiments.

FIG. 5A illustrates a schematic circuit for conventional SRAM Write Asist from lowering supply terminal voltage during a Write to improve Write Margins comes with the energy overhead of charging all transistor terminal connected to the net identified with heavy blue lines in schematic above, according to one or more embodiments.

FIGS. 5B and 5C are illustrations of graphs depicting Write VMIN improvement of a supply terminal, according to one or more embodiments.

FIG. 6A is a schematic illustration of a large array building block with 256b/BL& 256b/WL subarrays in a 128 Kb Macro, according to one or more embodiments.

FIG. 6B is a schematic illustration of a bit column peripheral circuits inserted at center of BL to enable larger BL/VS1, 2 capacitance divider ratio CBL:CVS1, 2 of 1:2, according to one or more embodiments.

FIG. 7 is an illustration of a 6T SRAM Bitpath schematic that harvests BL evaluation charge during a read access at the VS1, 2 terminals now no longer connected to GND, according to one or more embodiments.

FIG. 8 is an illustration of a graph of a SRAM scheme, according to one or more embodiments.

FIG. 9 is an illustration of a graph depicting a scheme that shrink pulse width to within 200 ps (25C, TT) in 16FF CMOS given faster sensing action, smaller BL signal swing and lessor variance seen from SA offsets and absence of noise from col mux and leakage noise from unselected cells, according to one or more embodiments.

FIG. 10 is an illustration of a model comparing variance of logic threshold of inverting amplifier as implemented in the proposed design (at 2/3 Vdd) with variance seen in bitpath at input of conventional DSAs, according to one or more embodiments.

FIG. 11 are illustrations of graphs of a comparison of voltage and current waveforms of the bitpath b/w use of conventional SRAM peripheral circuits (middle) and proposed ones (top), according to one or more embodiments.

FIG. 12 are illustrations of graphs depicting precharging BLs to a VT below VDD to enable a lower voltage on the cell storage node during a Read access and therefore a larger SNM when compared to conventional SRAM arrays, according to one or more embodiments.

FIG. 13 are illustrations of graphs showing reduction in BL Column power from 16.7 fJ per column in conventional SRAM to 3.15 fJ using proposed scheme-a reduction by a factor of 5.3 or a reduction of 81%, according to one or more embodiments.

FIG. 14 are illustrations of graphs of depicting a scheme having 1/3 to 1/2 the sensitivity to VT variations in the inverting amplifier as the DSA offsets while also not seeing as much read current uncertainty since the BL signal development time is half of conventional SRAMs and Read assist scheme used of lower noise injection into cell from BL does not degrade performance, according to one or more embodiments.

### DETAILED DESCRIPTION

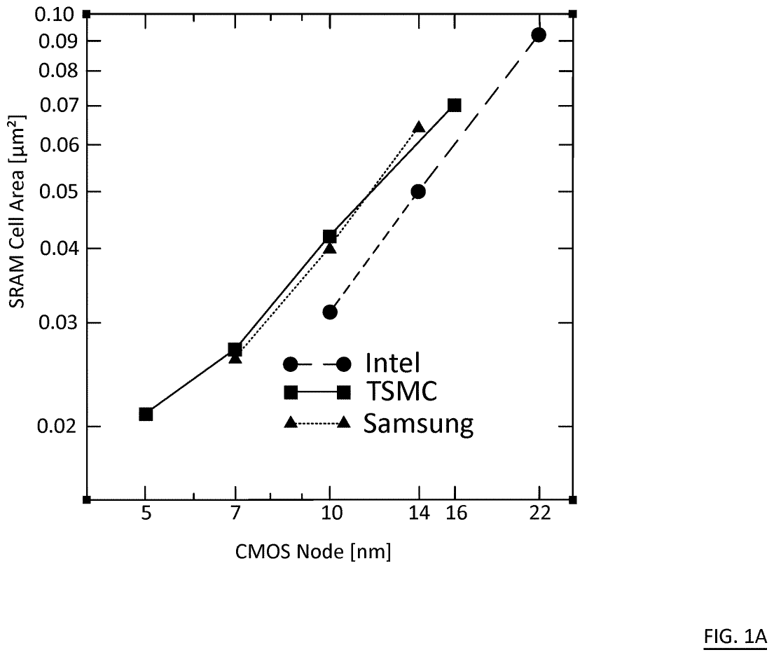

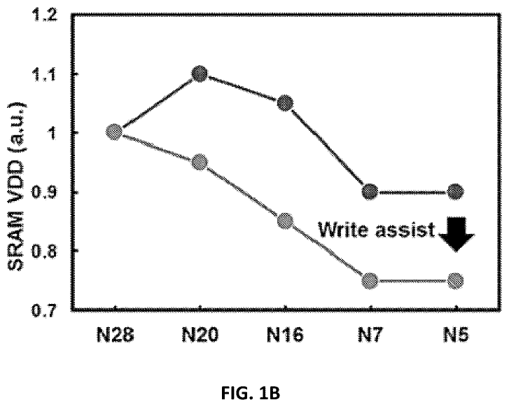

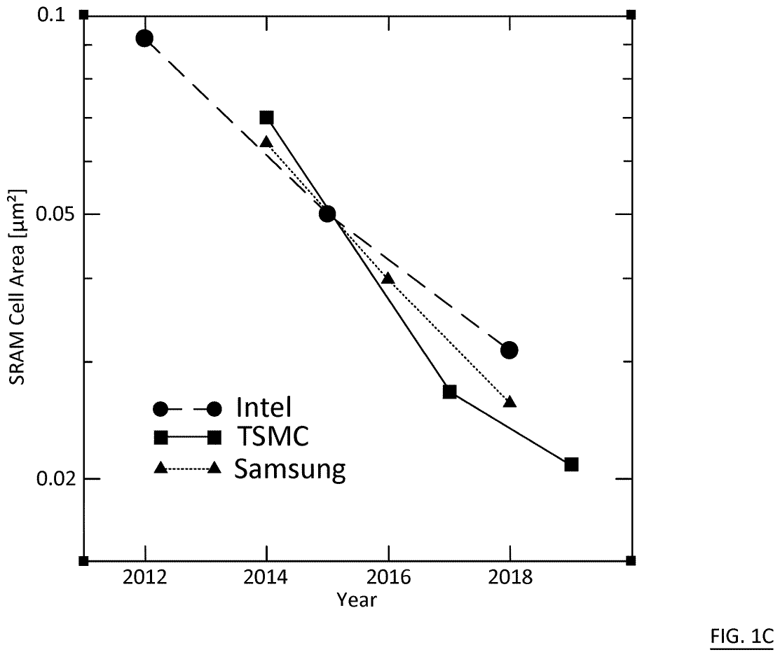

FIGS. 1A-1C are illustrations of graphs depicting SRAM Density Scaling Vs Node and Vs Year and an illustration of a graph depicting SRAM voltage scaling, according to one or more embodiments, according to one or more embodiments.

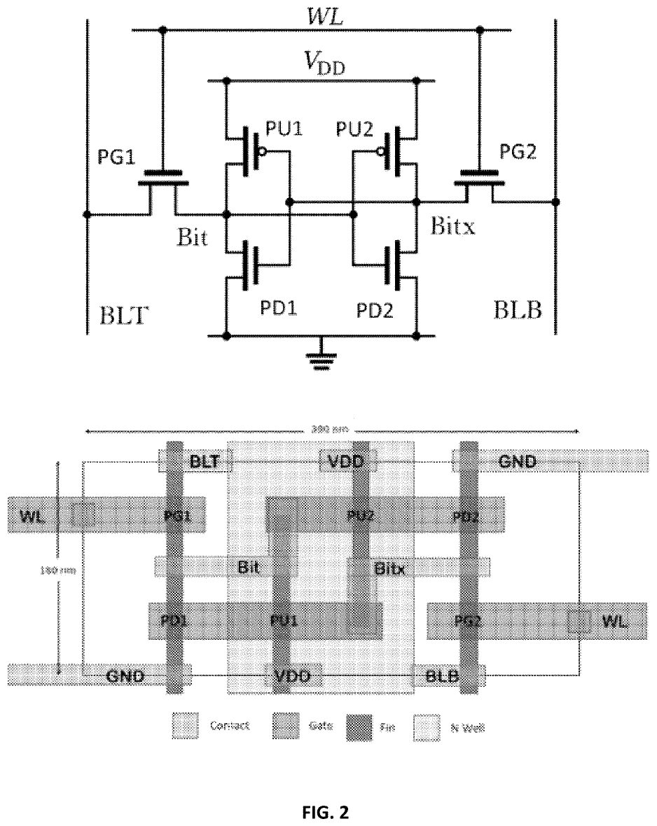

FIG. 2 illustrates a schematic circuit (top) and FinFET based layout for Dense 6T SRAM cell (bottom) with 1 fin for PG, PU, PD devices, according to one or more embodiments.

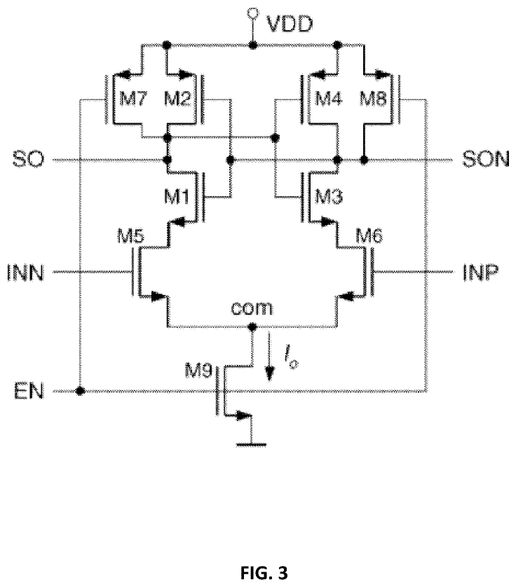

FIG. 3 illustrates a schematic circuit of a conventional high input resistance latch-type Differential Sense Amp (DSA), according to one or more embodiments. Conventional high input resistance latch-type Differential Sense Amp (DSA). Current flow of the differential input transistors M5 and M6 controls the serially connected latch circuit. A small difference between the currents through M5 and M6 converts to a large output voltage. A minimum input difference of VINP−VINN=VMIN=50 mV to 100 mV sufficient to resolve input differential voltage.

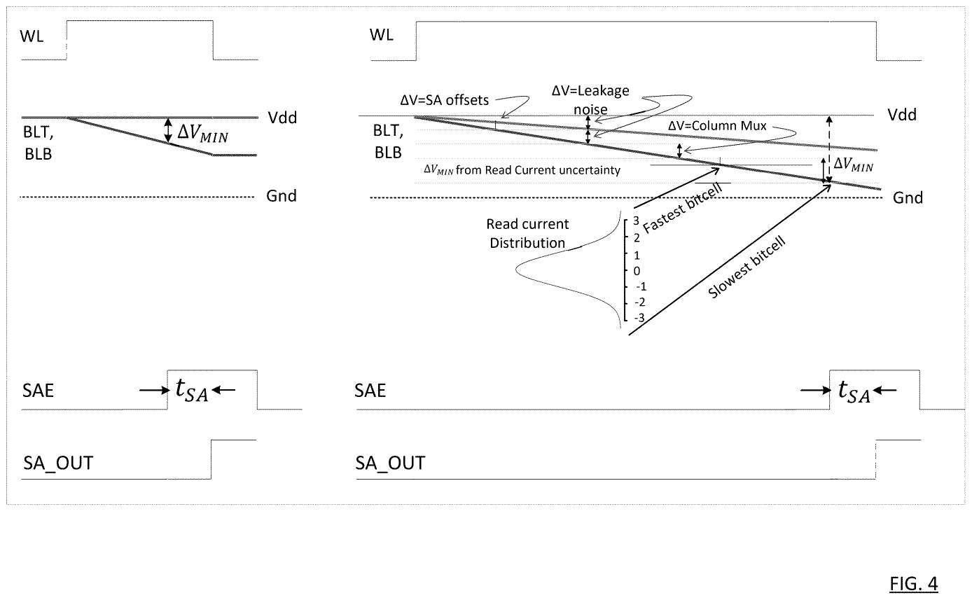

FIG. 4 is an illustration of a graph depicting presence of variability. along SRAM bitpath increases signal development time and BL voltage swing—degrading read performance and read energy efficiency with conventional DSAs, according to one or more embodiments. Presence of variability along SRAM bitpath increases signal development time and BL voltage swing—degrading read performance and read energy efficiency with conventional DSAs. Longer WL pulse widths become necessary to meet DSA timing requirements for slowest bitcell. All other bitcells have more time to discharge the BL and build larger signal, consuming more energy. The WL pulse width equals the minimum cycle time when large arrays support a pipelined L3 access, with the variability encountered in DSA schemes. directly setting limits on pipeline SRAM performance.

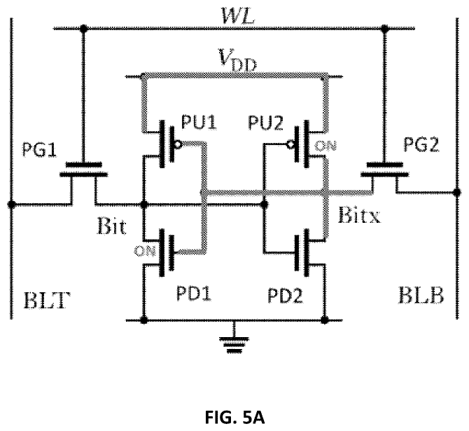

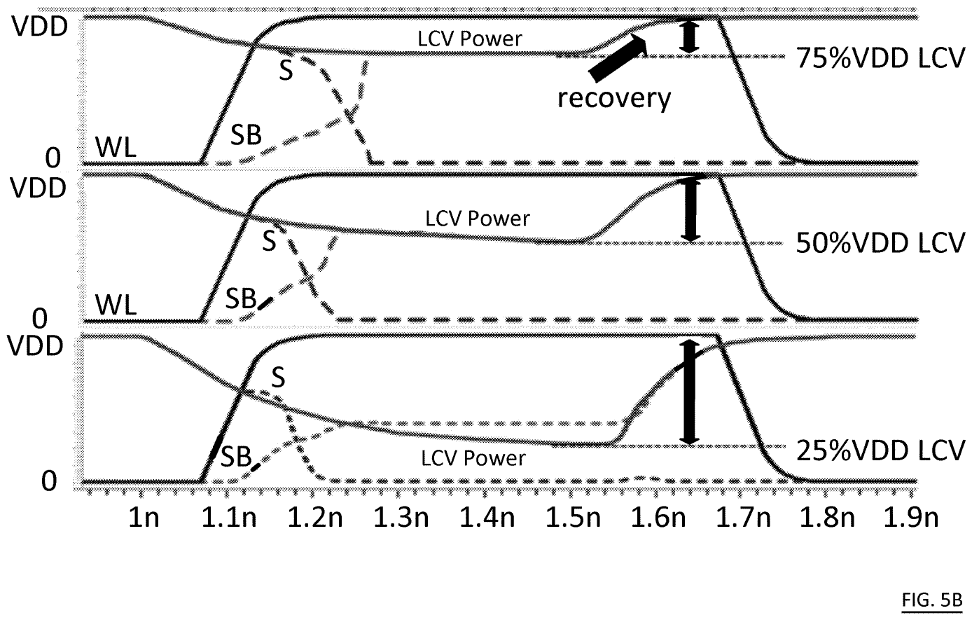

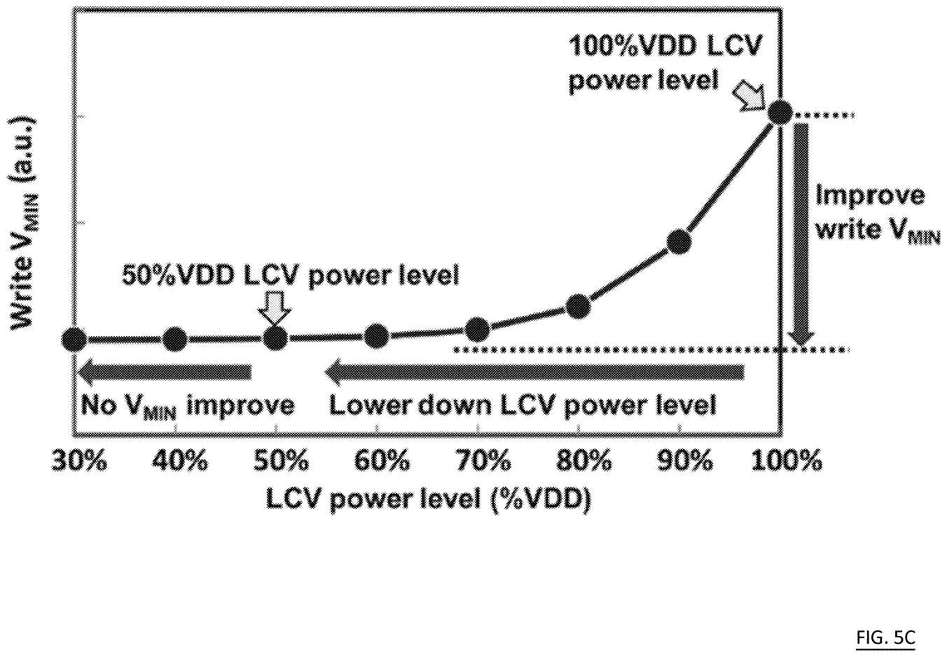

FIG. 5A illustrates a schematic circuit for conventional SRAM Write Assist from lowering supply terminal voltage during a Write to improve Write Margins comes with the energy overhead of charging all transistor terminal connected to the net identified with heavy blue lines in schematic above, according to one or more embodiments. FIGS. 5B and 5C are illustrations of graphs depicting Write VMIN improvement of a supply terminal, according to one or more embodiments. Conventional SRAM Write Asist from lowering supply terminal voltage during a Write to improve Write Margins comes with the energy overhead of charging all transistor terminal connected to the net identified with heavy blue lines in schematic above. The diffusion capacitance of the source terminals of the PFET, the diffusion capacitance of all 3 transistors connected to the storage node ‘Bitx’ and the gate input capacitance of the inverter transistors PU1 and PD1 together are about 4× larger than the BL terminal capacitance of the cell. The energy overhead to recover the voltage at the supply terminal is thus 4× the energy required for the same voltage swing on the BL. FIGS. 5B and 5C are illustrations of graphs depicting Write VMIN improvement of a supply terminal, according to one or more embodiments.

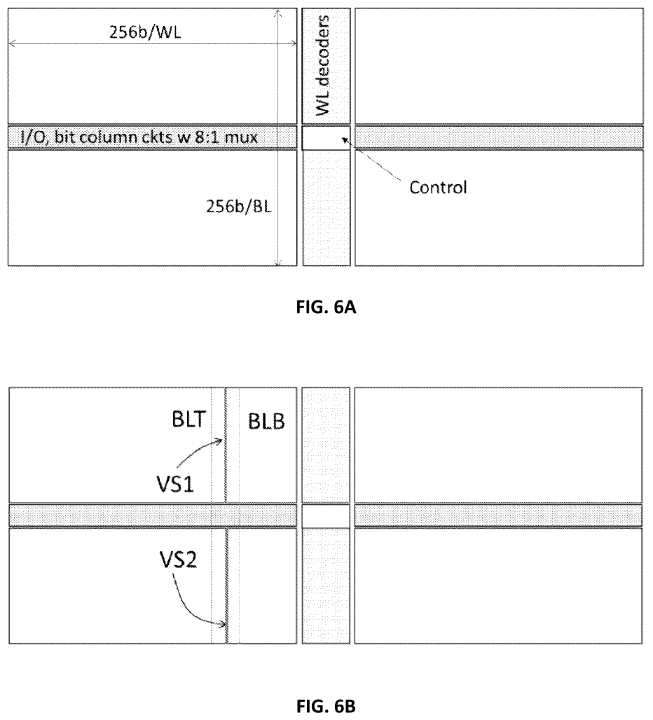

FIG. 6A is a schematic illustration of a large array building block with 256b/BL& 256b/WL subarrays in a 128 Kb Macro, according to one or more embodiments. Cw (wire)=1.15×256×0.390 μm×0.185fF/μm ~21.25 fF; Rw: R=0.95 ohms/sq with double metal lines RRWL=535 ohms; CBL (wire)=256×0.18 um×0.185fF/um×1.1~9.4fF; CVS1 (wire)=4.26fF. FIG. 6B is a schematic illustration of a bit column peripheral circuits inserted at center of BL to enable larger BL/VS1, 2 capacitance divider ratio CBL:CVS1, 2 of 1:2, according to one or more embodiments. If BL and VS1, 2 had identical lengths, CBL:CVS1, 2 would be 1:4 since the VSS terminal of the cell sees about 4× the capacitance as the BL terminal.

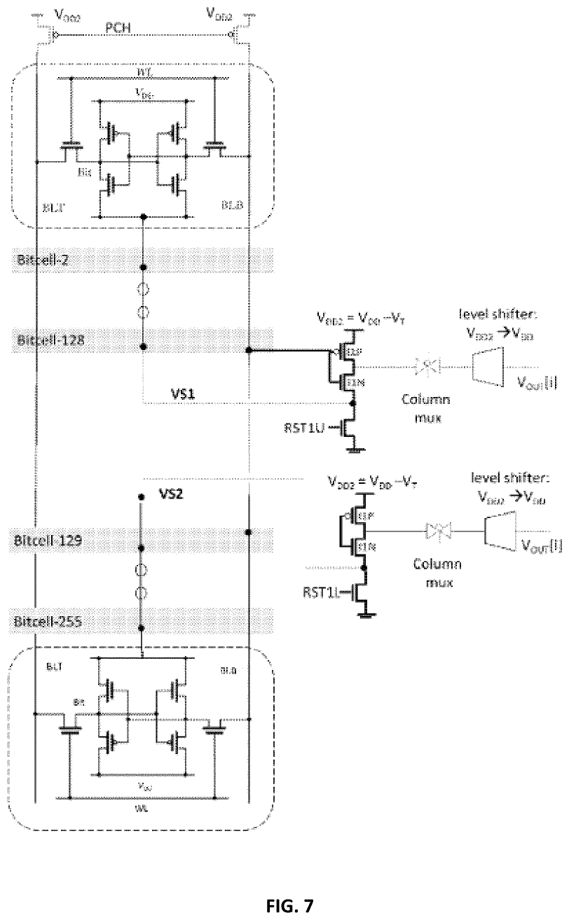

FIG. 7 is an illustration of a 6T SRAM Bitpath schematic that harvests BL evaluation charge during a read access at the VS1, 2 terminals now no longer connected to GND, according to one or more embodiments. Instead, it enables the inverting amplifier (I1P, I1N) with dynamic reset (RST1) to respond 2× faster while seeing 1/3 to 1/2 of the variance when compared to DSA. The voltage swing on the BL is fixed by capacitor divider b/w C_ and CVS1, 2 eliminating uncertainty of BL signal development. The BL precharges to VDD2-VT: a VT below VDD to increase SNM by minimizing injected noise into the cell from BL terminal and to lower the largest component of active SRAM power (BL precharge). Note that 256 bitcells drive the a single BL into 2 inverters with the lower inverter disabled with RST1L=0 and VS2 is pinned to a diode voltage above GND (0.17-0.2V) when the bottom subarray is unselected.

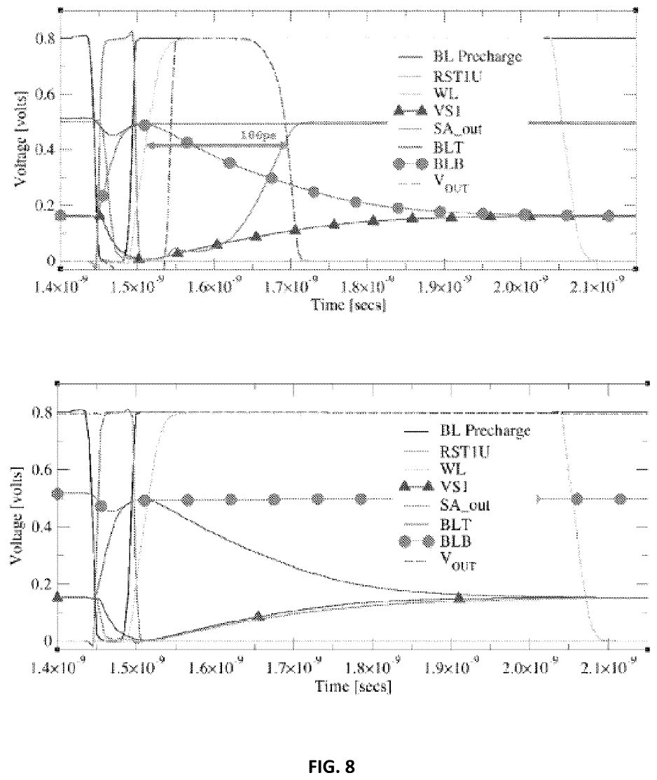

FIG. 8 is an illustration of a graph of a SRAM scheme, according to one or more embodiments. In the proposed SRAM scheme, Read access proceeds with the WL select transition without requiring timing enablement of sensing action. As the BL charge moves to VS1, the inverting amplifier output ‘SA_out’ switches when the difference b/w the decreasing input to the inverting amplifier and it's increasing logic threshold intersect. The response is much faster, less vulnerable to variability and signal swing is fixed-independent of read current, variance compared to conventional DSA based schemes. This because the signal dev rate across the inverting amplifier is twice that of the rate b/w the DSA inputs, the variance of the logic threshold is 1/3 to 1/2 of the DSA offsets (FIG. 10), column multiplexing done at output of SA (and not at its input as with DSA) and leakage noise much less due to leakage suppression with negative gate-source voltage for PG NFETs of all cells in column as BL charge transfers to VS1 (as seen in waveforms below). Also, note that the output, Vout switches within 200 ps of WL select despite 256b/L and that maximum possible swing on BL is ~330 mV. Note that that larger WL pulse widths do not increase energy dissipation or the voltage swing of the BL. The waveforms above and below correspond to data read from the bitcell of opposite polarity.

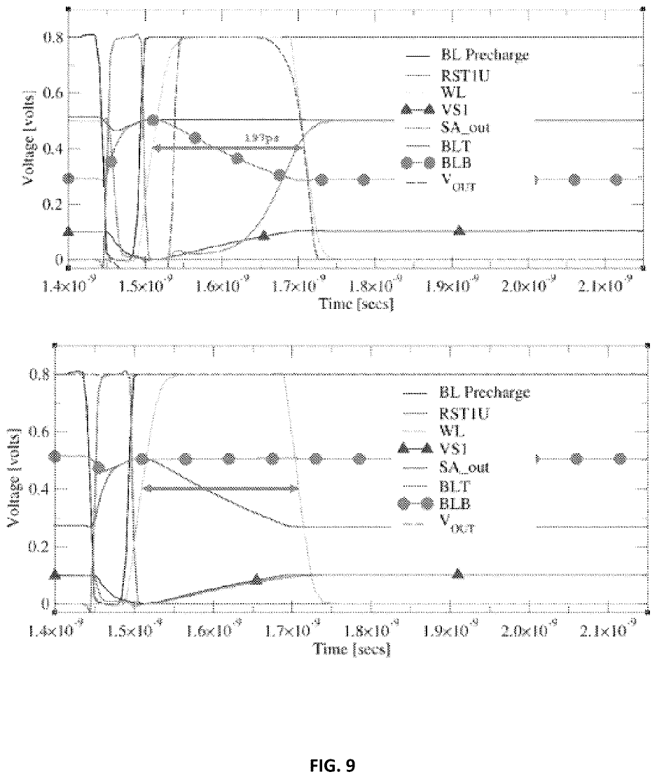

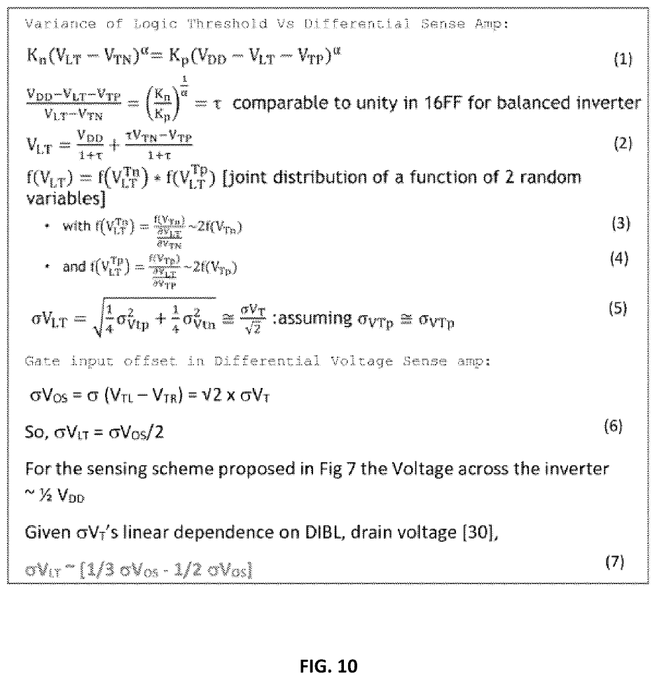

FIG. 9 is an illustration of a graph depicting a scheme that shrink pulse width to within 200 ps (25C, TT) in 16FF CMOS given faster sensing action, smaller BL signal swing and lessor variance seen from SA offsets and absence of noise from col mux and leakage noise from unselected cells, according to one or more embodiments. Minimum SRAM pipeline cycle time is set by the WL pulse width. The proposed scheme, can shrink pulse width to within 200 ps (25C, TT) in 16FF CMOS given faster sensing action, smaller BL signal swing and lessor variance seen from SA offsets and absence of noise from col mux and leakage noise from unselected cells. Note that at higher pipeline clock rates, the BL swing is smaller but sufficient for sensing action enabling higher energy efficiency during SRAM Read access than at slower clock rates.

FIG. 10 is an illustration of a model comparing variance of logic threshold of inverting amplifier as implemented in the proposed design (at 2/3 Vdd) with variance seen in bitpath at input of conventional DSAs, according to one or more embodiments.

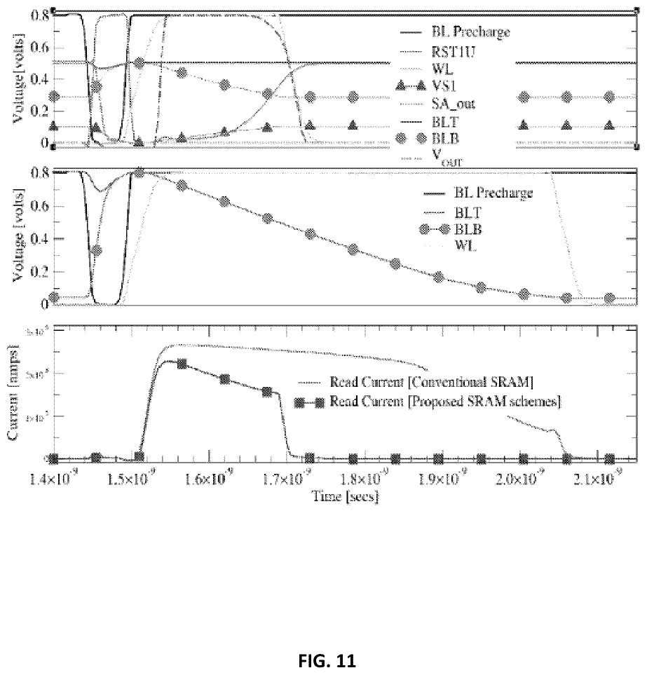

FIG. 11 are illustrations of graphs of a comparison of voltage and current waveforms of the bitpath b/w use of conventional SRAM peripheral circuits (middle) and proposed ones (top), according to one or more embodiments. Voltage across cell NFET stack (PG-PD) is almost half of that in a conventional SRAM from Precharging BLs to a VT below VDD and from harvesting charge at VS1. Signal development rate on the BL is double in the proposed scheme even though cell read currents (bottom) are less in proposed scheme than conventional SRAMs.

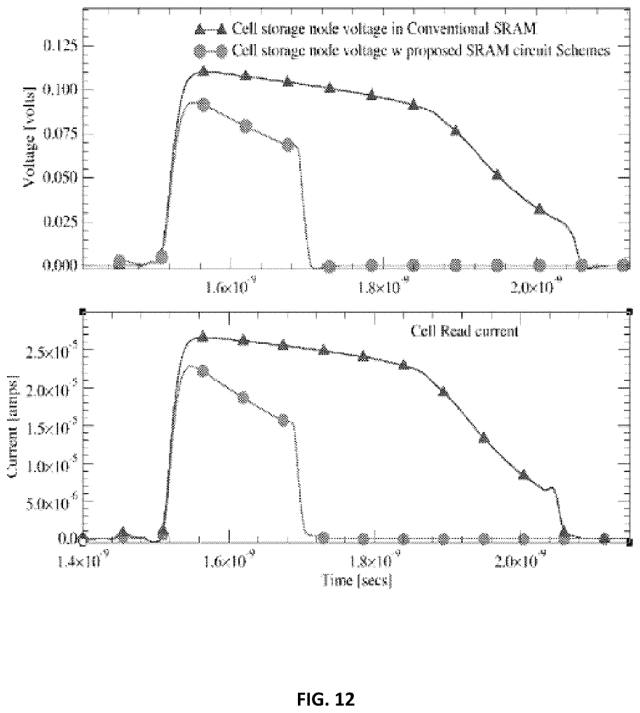

FIG. 12 are illustrations of graphs depicting precharging BLs to a VT below VDD to enable a lower voltage on the cell storage node during a Read access and therefore a larger SNM when compared to conventional SRAM arrays, according to one or more embodiments. As BL signal develops in the proposed scheme, read current and cell storage node voltage drop even further improving cell SNM by 10% at the start of the WL access to over 20% before the WL deselects. Unlike the conventional SRAM where cell storage node voltage or read current stay flat during WL select, proposed schemes increase cell immunity to noise until WL deselected (above, FIG. 9) or until the cell self-disables (FIG. 8). This without adding any transistors as area or energy overhead.

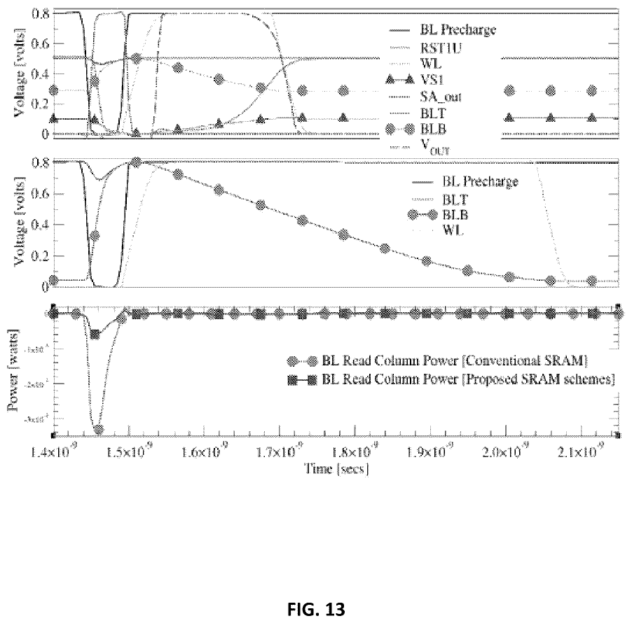

FIG. 13 are illustrations of graphs showing reduction in BL Column power from 16.7 fJ per column in conventional SRAM to 3.15 fJ using proposed scheme-a reduction by a factor of 5.3 or a reduction of 81%, according to one or more embodiments. BL power accounts for over half of the total SRAM active power for CIM applications warranting a separate lower bitpath power supply (of 0.5V in this example).

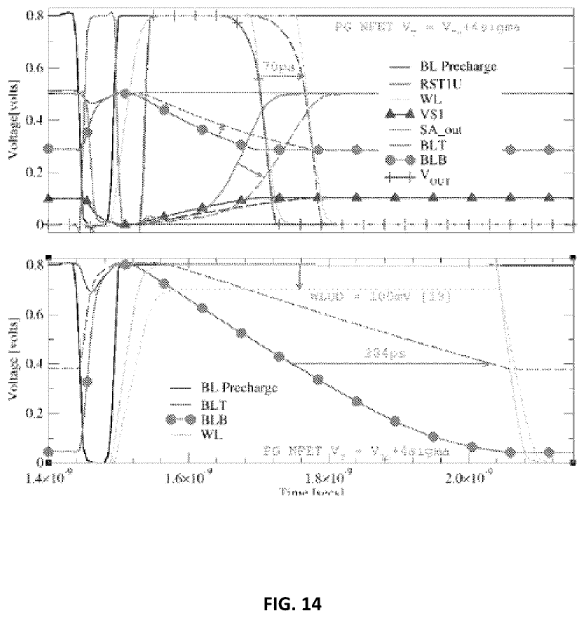

FIG. 14 are illustrations of graphs of depicting a scheme having 1/3 to 1/2 the sensitivity to VT variations in the inverting amplifier as the DSA offsets while also not seeing as much read current uncertainty since the BL signal development time is half of conventional SRAMs and Read assist scheme used of lower noise injection into cell from BL does not degrade performance, according to one or more embodiments. In conventional SRAM arrays, performance is limited by the worst case bitcell (assumed in this analysis with a 4 s increase in PG NFET VT only. Reduction of gate overdrive, with WLUD Read Assist schemes where the WL voltage is lower by 100 mV can contribute to additional performance degradation—seen above of 284 ps in BL signal development time compared to the 70 ps degradation in proposed scheme.

### 4. Proposed Circuit Schemes

Primary degradation of SRAM performance in conventional arrays originates in the differential sensing scheme. Fast sensing due to positive feedback with □VMIN of only 50 mV-100 mV is no longer possible for dense SRAM arrays on advanced CMOS platforms due to substantial variability encountered along the bitpath when using Differential Sense Amps (DSA). 4.1 Proposed Bitpath: The 6T SRAM Bitpath schematic (FIG. 7) that harvests BL evaluation charge during a read access at the VS1, 2 terminals are now no longer connected to GND. Instead, it enables the inverting amplifier (I1P, I1N) with dynamic reset (RST1) to respond 2× faster while seeing 1/3 to 1/2 of the variance when compared to DSA. The voltage swing on the BL is fixed by capacitor divider b/w CBL and CVS1, 2 eliminating uncertainty of BL signal development. The BL precharges to VDD2-VT: a VT below VDD to increase SNM by minimizing injected noise into the cell from BL terminal and to lower the largest component of active SRAM power (BL precharge).

FIG. 6b and FIG. 7 show that the VS1, 2 charge harvesting nodes are less than half the length and are connected to half as many bitcells as the BL pair—BLT and BLB. The caption of FIG. 6a quantifies the wiring contribution to the capacitance of these nodes and the caption of FIG. 6b quantifies the ratio of the capacitance of VS to BL in a bitcell (including the wire) as 4:1. Thus, a BL twice as long as VS can be expected to see a VS to BL capacitance ratio of 2:1 and thus see (a discharged) VS rise to a voltage 1/3 of the precharge voltage on the BL. In FIG. 8, with a precharge voltage of 0.5V, the charge harvesting node VS1 thus rises to 1/3 of 0.5V=1.67 V.

This charge on VS1 (128 bitcells tall) is shared with the V2 grid (not shown in FIG. 7 to avoid cluttering it, but shown in FIG. 8 of the Register File array paper for the Global Read BL by turning on NFET GBR1 to share charge harvested on V2G to V2) before a Read or Write Access begins. In a 6T SRAM cell array since a local/global BL hierarchy is not used (due to limited number of metal tracks across a narrower bitcell when compared to the Register File bitcell and the need for higher array area efficiency in large L2, L3 6T, SRAM arrays in CPUs or large SRAM array buffers in accelerators), the 256-bit long bitline pair is used directly for Read and Write operations without a BL hierarchy. For a Write that follows a Read, each bitline pair could harvest the charge on the BL in the pair that is intended to he driven to a ‘0’. This is accomplished by comparing the present voltage of the BL with the data in voltage to selectively discharge the BL in the pair to V2. Since Writes. do not take as long as a Read access (which has a larger latency than a Write due to sensing action) the delay overhead in comparing old Vs new values of EL voltage to selectively discharge the BL in the pair does not increase 6T SRAM cycle time or its pipeline performance.

Charge harvested from VS1, 2 in each column to V2 following a Read access and from the BL pair before a Write access. is used by write drivers to write to the BL pair during a Write access—just as is described for Register File arrays in Provisional Patent Applications 63/115,591 & 63/138,456.

In the proposed SRAM scheme, a Read access proceeds with the WL select transition without requiring timing enablement of sensing action. As the BL charge moves to VS1 (FIG. 8), the inverting amplifier output ‘SA out’ switches when the difference b/w the decreasing input to the inverting amplifier and it's increasing logic threshold. intersect. The response is much faster, less vulnerable to variability and signal swing is fixed—independent of read current variance compared to conventional DSA based, schemes. This because the signal dev rate across the inverting amplifier is twice that. of the rate b/w the DSA inputs, the variance of the logic threshold is 1/3 to 1/2 of the DSA offsets (FIG. 10), column multiplexing done at output of SA (and not at its input as with DSA) and leakage noise. much less due to leakage suppression with negative gate-source voltage for PG NFETs of all cells in column as BL charge transfers to VS1 (as seen in waveforms below). Also, note that the output, Vout switches within 200 ps of WL select despite 256b/L and that maximum possible swing on BL is ~330 mV. Note that larger WL pulse widths do not increase energy dissipation.

VS1 is the node that stores evaluation charge. The ground terminal of the bitcells in the column are connected to this common node. So, when a cell is selected to read, charge from the BL moves to VS1 raising its voltage (reset to GND directly before a Read begins). When VS1 rises to within a VT of the decreasing BL voltage, there isn't enough overdrive on the PG NFET in the selected bitcell to keep it turned on. Hence the self-disabling of a Read access. Stored charge is used to disable the bitcell exactly when it is no longer needed. By self-disabling the cell access, bitlines do not continue discharging even though the WL is still selected. This alone contributes to a large reduction of otherwise wasted energy in conventional SRAM arrays.

4.2 Pipeline Performance: Minimum SRAM pipeline cycle time is set by the WL pulse width. The proposed scheme can shrink pulse width to within 200 ps (25C, TT) in 16FF CMOS (FIG. 9) given faster sensing action, smaller BL signal swing and lesser variance seen from SA offsets and absence of noise from col mux and leakage noise from unselected cells. Note that at higher pipeline clock rates, the BL swing is smaller but sufficient for sensing action enabling higher energy efficiency during SRAM Read access than at slower clock rates (FIG. 9).

4.3. Comparison with Conventional SRAM: FIG. 11 compares voltage and current waveforms of the bitpath. of a conventional SRAM (middle) with proposed schemes (top). Voltage across the cell NFET stack (PG-PD)—between BLT and VS1, is almost half of that in a conventional SRAM while the signal is being developed in proposed scheme. Cell read currents (bottom) are less in proposed scheme than in conventional SRAMs because the voltage across the read stack is almost half that in a conventional bitpath. Lower read current helps cell stability during read since less noise is injected into the cell when selected by the WL. The sense action is much faster in proposed scheme since sensing is dual ended b/w BL and VS1.

4.4 Read Assist in Proposed Bitpath: Precharging BLs to a VT below VDD enables a lower voltage on the cell storage node during a Read access and therefore a larger SMN when compared to conventional SRAM arrays. As BL signal develops in the proposed scheme (FIG. 12), read current and cell, storage node voltage drop even further improving cell SNM by 10% at the start of the WL access to over 20% before the WL deselects, Unlike conventional SRAM where cell storage node voltage or read current stay mostly flat during WL select, proposed scheme increases cell immunity to noise until WL deselected (FIG. 11, FIG. 9) or until the cell self-disables (FIG. 8). This without adding any transistors as area or energy overhead.

4.5 Energy Efficiency in proposed scheme: FIG. 13 compares time dependent power dissipation between conventional and proposed schemes (area under power equals total energy consumed per column). BL power accounts for over half of the total SRAM active power typically when 128-256 bit columns, (each 256-512 bits long) are accessed concurrently to develop signal warranting a separate lower bitpath power supply (of 0.5V in this example). Lower Bitpath power supply is advantages because (i) performance is higher due to smaller voltage swing (ii) active power is lower (iii) SNM improves due to lower noise injected into cell and (iv) easier to interface SRAM data with logic—that generally has much lower VMIN than SRAM. Proposed schemes show reduction in BL Column power from 16.7 fJ per column in conventional SRAM to 3.15 fJ using proposed scheme—a reduction by a factor of 5.3 or a reduction of 81%.

4.6 Impact of variability. and Read Assist schemes on performance: In conventional SRAM arrays, performance is limited by the worst case bitcell (assumed in simulation shown in FIG. 14 with a 4σ increase in PG NFET VT only). Reduction of gate overdrive by 100 mV with WLUD Read Assist schemes is also assumed in the conventional SRAM simulation. WLUD can contribute to additional performance degradation—seen cumulatively in FIG. 14 as 284 ps in BL signal development time compared to the 70 ps degradation in proposed scheme. Proposed scheme has 1/3 to 1/2 the sensitivity to VT variations. (FIG. 10) in the inverting amplifier when compared to DSA offsets. while also not seeing as much read current uncertainty since the BL signal development time is half of conventional SRAMs and Read assist scheme used of lower noise injection into cell from BL does not degrade performance.

5. Scalability of proposed harvesting schemes in 6T SRAM arrays For the reasons in the 3 items highlighted below, proposed 6T SRAM circuits are expected to be more scalable than published industry-best 6T SRAM arrays. Proposed 6T SRAM arrays are also more responsive to performance on metrics of performance and energy efficiency demanded by hardware in the datacenter and in the wireless space for training and for inferencing AI workloads. More likely than not, large SRAM arrays have lower FMAX than earlier FinFET based designs. For example, in ref, the maximum SRAM (pipeline) FCLK in a 273 Kb macro for which data is reported on a 10 nm FinFET platform is 1.8 GHz. In ref the max (pipeline) FCLK for a 144 Kb macro or a 5 nm FinFET platform is 2.1 GHz. Older publications report pipeline Fmax of over 4 GHz for comparably sized arrays

Highlight of the proposed 6T SRAM charge harvesting peripheral circuits are: 1. Enables higher energy efficiency without lowering operating voltages from use of harvested charge to self-disable read current while also eliminating uncertainty of signal amplitude on all bitlines—which is the largest energy overhead in conventional SRAM array designs. Secondly, elimination of energy, performance and area overheads incurred with conventional Read/Write Assist schemes and elimination of bitline leakage noise—both also from use of harvested charge further improve energy efficiency in proposed 6T SRAM arrays. These improvements do not require changes to the CMOS process, bitcell or design/test floW8. The improvements in energy efficiency are accompanied by improvements in access time latency and pipeline performance (reviewed in 2. below) enabling an order of magnitude improvement in the energy-delay product over best reported SRAM array designs by industry.

2. Lowers bitpath delay and delay variability from use of novel, robust and compact sensing schemes that double the BL signal development speed from use of harvested charge and which see 1/3-1/2 the variance of conventional differential sensing. Self-triggering of sensing action and self-disabling of bitcell read eliminate other uncertainty contributions to. latency in conventional SRAM bitpaths such as mismatch in path delays between the sense control path and the bitpath. Moreover, elimination of bitline leakage noise from harvesting action and elimination of parasitic contributions by conventional column multiplexers along with use of assist schemes that do not degrade bitpath delay variability or burden the bitpath with energy, latency and area overheads—all contribute to. substantially lowering the uncertainty of bitpath delay using proposed schemes-enabling as much as a 2-3× improvement in pipeline array performance. This improvement in performance multiplies with the improvement in energy efficiency in 1. above to yield an order of magnitude improvement in the energy-delay product, The analysis in this paper includes the maximum impact of cell VT on bitpath latency in FIG. 14 and compares the degradation of bitpath latency in proposed scheme to that of conventional SRAM schemes reported by industry members showing a 4:1 advantage in WL select to sense amp output delay degradation.

3. Other metrics of higher reliability from use of harvested charge to lower voltages across terminals of “always-on” bitcell transistors improves the reliability degradation from voltage accelerated aging mechanisms. Higher array area efficiencies can be accomplished from elimination of circuits for R/W assist schemes, use of compact sensing schemes with fewer transistors and lower transistor area overheads from use. of self-triggering sensing action and self-disabling bitcell access.

This Non-Provisional Patent Application is an extension of previously filed Provisional Patent Applications 63/144,458 & 63/194,053. CMOS: harvesting circuits on 8T 1R1W 2-port Register File arrays are extended to conventional 6T SRAM bitcell arrays enabling substantial improvements to SRAM access time, pipeline performance and to its active and leakage energy dissipations—without scaling operating voltages while also improving Read and Write margins using assist schemes at zero area and energy overhead by reusing circuits that harvest charge. Active energy dissipation during an SRAM read, access is lowered by over 80% by use of novel sensing schemes that self-limit signal development on the BL without the energy overheads seen in conventional designs from sense-amp offsets, BL column leakage and uncertain read current. Improvements of 1.5×-2× in access time are enabled by doubling the signal development rate on the BL—from comparing the rising electric potential of harvested charge with a decreasing BL voltage in a bitcell column using a novel and compact 3-transistor inverting amplifier with dynamic reset. This area and energy efficient scheme leveraging availability of harvested charge not only self-limits signal development on the BL to improve read, latency, but also eliminates the uncertainty of BL signal swing using a capacitive divider to deliver higher precision in resolving input data vectors when used for compute-in-memory applications.

While Read assist techniques reported by industry typically weaken the bitcell access transistors by under-driving the WL, they also increase the uncertainty of read current, substantially increasing the performance penalty that margining requirements of the slowest bitcell impose on WL pulse width with differential sensing. In the proposed scheme, FL swing is predefined by capacitive dividers and BL signal is resolved from triggering the logic threshold of the inverting amplifier at much lower vulnerability to MOS device variation—at double the signal development rate. The proposed read, write assist scheme leverages the rising voltage of the harvesting node during a read to minimize the injected charge from the BL to the cell node until the bitcell self-disables at which point the Read margin equals the much higher retention margin of the bitcell. During a Write, the raised voltage of the column harvesting node weakens the selected cell PFET holding a ‘1’ at the storage node enabling a Write operation at higher Write Margins. Unlike conventional assist methods, there is zero overhead in area because no additional transistors are added accomplish improvements in Read and Write margins.

Charge harvested in each column of bitcells from a read/write access is moved to a local harvest grid with a fraction of the capacitance of the BLs accessed in the subarray, at a voltage closer to VDD and is readily tapped into during a following Write access lowering its energy consumption from the power grid by over 30%. Active or standby mode leakage is lowered by the raised voltage of the harvesting node in each column-that is discharged only directly before the WL selects for all columns during a Read and for half-select columns during a Write.

1. (canceled)

2. A transistor memory device, comprising:
a complementary metal-oxide-semiconductor (CMOS) inverter with a gate input terminal, a supply voltage terminal, a ground terminal, and an output terminal, the ground terminal configured to be coupled to a reference ground terminal of the transistor memory device via a field-effect transistor, a change in a first voltage signal configured to be developed by a transistor storage element at the gate input terminal during a read data access in which (1) the ground terminal is decoupled from the reference ground terminal and (2) the field-effect transistor is in an off state, a second voltage signal that is of opposite polarity to the first voltage signal configured to change at the ground terminal, the ground terminal configured to reset to a reference ground potential of the transistor memory device (1) by activation of the field-effect transistor via an activating pulse at a gate input of the field-effect transistor, (2) before the first voltage signal is developed by the transistor storage element, and (3) before the second voltage signal is changed at the ground terminal.

3. The transistor memory device of claim 2, wherein:
the transistor storage element includes (1) at least one word line terminal that is activated to select the transistor storage element for the read data access (2) at least one bitline terminal that develops a voltage or current signal in response to the transistor storage element being selected for the read data access and (3) a source terminal configured to develop the second voltage signal.

4. The transistor memory device of claim 2, further comprising:
a first plurality of transistor storage elements that share a common bitline terminal, a second plurality of transistor storage elements being a subset from the first plurality of transistor storage elements sharing a common source terminal; and
a third plurality of transistor storage elements that share a common word line terminal, each transistor storage element from the third plurality of transistor storage elements is (1) a transistor storage element from the first plurality of transistor storage elements and (2) a transistor storage element from the second plurality of transistor storage elements.

5. The transistor memory device of claim 4, wherein:
the common bitline terminal is coupled to the gate input terminal,
the common source terminal is a harvest node,
the common source terminal is coupled to the ground terminal of the CMOS inverter, and
the source terminal of the transistor storage element is configured to electrically decouple from the reference ground potential during the read data access.

6. The transistor memory device of claim 5, further comprising:
a capacitive divider electrically connected between the common bitline terminal and the common source terminal, the common bitline terminal having a capacitance proportional to a number of transistor storage elements in the first plurality of storage elements, a capacitance of the common source terminal proportional to a number of transistor storage elements in the second plurality of transistor storage elements.

7. The transistor memory device of claim 6, wherein:
a magnitude of a voltage signal developed on the common source terminal relative to a magnitude of a voltage signal developed on the common bitline terminal is determined by the capacitive divider between the common bitline terminal and the common source terminal.

8. The transistor memory device of claim 7, wherein:
the capacitive divider is configured to increase the voltage signal at the common source terminal to be within a predefined limit to retain data in the first plurality of transistor storage elements and the second plurality of transistor storage elements.

9. The transistor memory device of claim 8, wherein:
increasing the voltage signal at the common source terminal (1) increases an effective signal development rate asserted between the gate input terminal and the ground terminal of the CMOS inverter, (2) lowers an active energy of the read data access by allowing the transistor storage element to develop a smaller voltage signal at the common bitline terminal and (3) lowers a voltage difference between transistor storage element terminals improving a reliability degradation from a voltage accelerated aging mechanisms.

10. The transistor memory device of claim 9, wherein the transistor memory device is configured to resolve data in a subthreshold region where the CMOS inverter maintains larger than unity gain, the CMOS inverter configured to quantize binary signals with the capacitive divider enabling an increased voltage signal development rate at the common source terminal.

11. The transistor memory device of claim 10, wherein:
the field-effect transistor is a first field-effect transistor, the common bitline terminal is configured to be precharged to at least one of a supply voltage of the transistor memory device or to logic 1 in response to coupling the common bitline terminal to the supply voltage terminal through a second field-effect transistor (1) during the read data access and (2) before a transistor storage element in the first plurality of transistor storage elements is selected by activating the common word line terminal.

12. The transistor memory device of claim 11, wherein:
in response to precharging the common bitline terminal to the at least one of the supply voltage of the transistor memory device or to the logic 1, the common bitline terminal is configured to be decoupled from the supply voltage terminal of the CMOS inverter while the supply voltage terminal is held at the supply voltage.

13. The transistor memory device of claim 12, wherein:
the transistor storage element in the first plurality of transistor storage elements selected by activating the common word line terminal is configured to drain charge on the common bitline terminal by lowering a voltage at the common bitline terminal from the supply voltage.

14. The transistor memory device of claim 13, wherein:
the charge drained from the common bitline terminal is configured to be collected at the common source terminal during the read data access and raise an electric potential of the common source terminal.

15. The transistor memory device of claim 14, wherein:
raising the electric potential of the common source terminal and lowering the voltage at the common bitline terminal (1) self-limits a flow of current from the common bitline terminal to the common source terminal and (2) self-disables current flow when the voltage at the common bitline terminal is within a predetermined range of a metal-oxide-semiconductor field-effect transistor threshold voltage and above the common source terminal, a read current disabled while word line terminal is active to lower an energy and latency overhead.

16. The transistor memory device of claim 15, wherein:
the common source terminal at an elevated electric potential reverse biases a source body junction of an n-channel metal-oxide-semiconductor (NMOS) transistor at the transistor storage element for at least one transistor whose source terminal is coupled to the common source terminal and whose body terminal is coupled to the reference ground potential, the reverse biases at the source body junction enabling a reduction in a subthreshold leakage of the NMOS transistor.

17. The transistor memory device of claim 13, wherein:
the CMOS inverter does not use a sense amp enable signal and reduces latency overhead, energy overhead, and area overhead, the output terminal configured to self-trigger a low-to-high transition at the output terminal in response to a decreasing voltage at the gate input terminal being substantially equal to a rising trip voltage of the CMOS inverter.

18. The transistor memory device of claim 14, wherein:
the voltage signal developed on the common bitline terminal is determined by the capacitive divider, a voltage swing at the common bitline terminal fixed by the capacitive divider.
